(19) United States
(12) Patent Application Publication
(10) Pub. No.: US 2026/0349039 A1
(43) Pub. Date: Nov. 5, 2026

(54) BATTERY FAULT DETECTION METHOD AND SYSTEM BASED ON QUANTILE AND EXPONENTIALLY WEIGHTED ADAPTIVE NORMALIZATION

(71) Applicant: Chongqing University, Chongqing (CN)

(72) Inventors: Xiaosong HU, Chongqing (CN); Kai ZHANG, Chongqing (CN); Jiayi SONG, Chongqing (CN); Jinwen LI, Chongqing (CN); Jiacheng LI, Chongqing (CN); Shengman LI, Chongqing (CN)

(73) Assignee: Chongqing University, Chongqing (CN)

(21) Appl. No.: 19/712,277

(22) Filed: Jun. 18, 2026

(30) Foreign Application Priority Data
Jun. 19, 2025 (CN) 202510823908.0

(51) Int. Cl. G01R 31/367; B60L 3/00; B60L 58/26; G01R 31/3842; G01R 31/396; G07C 5/08

(52) U.S. Cl. CPC G01R 31/367; B60L 3/0046; B60L 58/26; G01R 31/3842; G01R 31/396; G07C 5/0808; G07C 5/0825; B60L 2240/547; B60L 2250/10

(57) ABSTRACT

A battery fault detection method based on quantile and exponentially weighted adaptive normalization includes: S1: collecting electric vehicle (EV) operational data including cell voltage data of each cell in a battery pack and time parameters, and performing data preprocessing; S2: performing Kalman filtering on the cell voltage data; S3: performing normalization processing on the filtered cell voltage data, including using quantiles to determine a normal value range, applying an exponentially decaying function to normal values, and applying an exponentially increasing function to outliers; S4: calculating a Dynamic Time Warping (DTW) distance between each pair of normalized cell voltage time series, and calculating a standard score (Z-score) of the distances; S5: setting a fixed threshold, and determining whether each battery cell has a fault by determining whether the standard score (Z-score) of the cell voltage exceeds the set threshold.

### CROSS-REFERENCE TO RELATED APPLICATIONS

This application claims priority to Chinese Patent Application No. 202510823908.0, filed on Jun. 19, 2025, the content of which is incorporated herein by reference in its entirety.

### TECHNICAL FIELD

The present application relates to the technical field of battery fault detection, and in particular to a battery fault detection method and system based on quantile and exponentially weighted adaptive normalization.

### BACKGROUND

With the widespread application of electric vehicles, traction batteries serve as their core components, and their performance and safety have attracted significant attention. Accurate and timely detection of battery faults is of great significance for ensuring reliable operation and service life of electric vehicles. Existing battery fault detection methods mainly rely on threshold judgment of directly measured values such as voltage, current, and temperature, as well as some traditional data processing techniques, such as Z-score normalization and Min-Max normalization. These methods can identify abnormal states of batteries to a certain extent, but have certain limitations. For example, Z-score normalization is sensitive to outliers, and outliers may cause distortion of the normalized data, affecting the accuracy of fault detection. Methods such as Min-Max normalization may fail to effectively amplify the difference between outliers and normal values, causing potential fault features to be masked. Furthermore, existing normalization methods mostly adopt a uniform scale for processing, without distinguishing between normal values and potential outliers, lacking differentiated modelling for the heterogeneity of the two, having poor adaptability to differences among individual battery cells, unable to well handle characteristic differences among cells in a battery pack, and exhibiting insufficient robustness in the face of complex operating condition changes and noise interference, being prone to false alarms or missed detections.

Furthermore, existing Battery Management Systems (BMS) face more complex challenges in actual on-board operating environments. During vehicle driving, continuous vibration and shock, sampling noise caused by electromagnetic interference, dynamic changes in battery State of Charge (SOC) and temperature, as well as capacity degradation and parameter drift of individual battery cells during long-term cyclic use, make fault detection methods based on fixed voltage thresholds or traditional statistical normalization difficult to maintain stable and reliable performance. Fixed threshold methods have poor adaptability to individual cell specificity differences and operating condition changes, easily leading to false alarms or missed detections; while traditional Z-score or Min-Max normalization methods may cause feature information distortion or fault signals being averaged and flattened when processing battery data containing outliers or noise. Moreover, high-complexity models such as deep learning and neural networks, although performing well in offline environments, are difficult to deploy directly on the vehicle side due to the computational power, storage capacity, and real-time constraints of the on-board BMS main control processor (MCU).

In view of the above problems, there is an urgent need for a more effective battery fault detection method that combines both robustness and anomaly sensitivity for real-time electric vehicle traction batteries through normalization.

### SUMMARY

In view of the foregoing, an objective of the present application is to provide a battery fault detection method and system based on quantile and exponentially weighted adaptive normalization, which can effectively suppress the interference of outliers on the overall distribution while enhancing the expression of potential weak anomaly information, thereby improving the performance and stability of data-driven methods in battery fault detection, and particularly realizing online lightweight deployment without requiring a large amount of historical data and complex models.

To achieve the above objective, the present application provides the following technical solution.

A battery fault detection method based on quantile and exponentially weighted adaptive normalization includes the following steps:
S1: collecting operational data of an electric vehicle (EV), comprising cell voltage data of each cell in a battery module and time parameters, and performing data preprocessing;
S2: performing Kalman filtering processing on the cell voltage data of the cells in the battery module;
S3: performing normalization processing on the cell voltage data after the filtering processing, comprising using quantiles to determine a normal value range, applying the exponentially decaying function to normal values, and applying the exponentially increasing function to outliers;
S4: calculating a Dynamic Time Warping (DTW) distance between each pair of normalized cell voltage time series, and calculating a standard score (Z-score) of the distances;
S5: setting a fixed threshold, determining whether the standard score of the cell voltage exceeds the set threshold, thereby determining whether each battery cell has a fault; and
S6: after determining that a target battery cell has a fault, executing different levels of physical protection and control responses by a main processor of a Battery Management System (BMS), so as to realize closed-loop protection from fault detection to physical safety execution.

Further, the step S1 specifically comprises the following steps:
S11: collecting normal operational data of the electric vehicle (EV), comprising a total voltage, each cell voltage, time parameters, and a Battery Management System (BMS) alarm signal;
S12: performing data processing and data cleaning on the cell voltage, and filling missing values of the data; and
S13: establishing a traction battery operational database based on the collected operational data of the battery module and each battery cell.

Further, the step S2 specifically comprises the following steps:
S21: determining an initial state estimation and an estimation error covariance based on the processed cell voltage data;
S22: using a mean and a variance of the first few data points as the initial state estimation, predicting a state at a current time point by using a state estimation at a previous time point, and updating the estimation error covariance;
S23: calculating a Kalman gain based on a current measurement value, correcting the predicted state to obtain a more precise estimation, and updating the estimation error covariance; and
S24: performing filtering processing on each cell voltage time series, wherein a filtering process outputs a smoothed and stable data sequence at each time point.

Further, the step S3 specifically comprises the following steps:
S31: using quartiles to determine the normal value range, a lower limit of the normal value range being calculated as follows:

Q₁−1.5·IQR;
an upper limit of the normal value range being calculated as follows:

Q₃+1.5·IQR;
wherein Q₁ represents a first quartile, which is a 25th percentile of the cell voltage data; Q₃ represents a third quartile, which is a 75th percentile of the cell voltage data; IQR is a difference between the third quartile Q₃ and the first quartile Q₁ in the cell voltage data set, expressed as follows:

IQR=Q₃−Q₁;
S32: based on the determined normal value range, determining normal values and outliers of the cell voltage, wherein cell voltage data within the upper and lower limit interval of the normal value range are normal values, and cell voltage data outside the upper and lower limit interval of the normal value range are outliers;
S33: applying the exponentially decaying function to the normal values, calculated as follows:

$${Z}_{α} = \frac{{x}_{i} - median}{α \cdot IQR} ,$$

$${X}_{normal \_ norm} = {e}^{- {Z}_{α}} ;$$

wherein Xᵢ represents a voltage value of each cell i; median represents a median of cell voltages, which is a cell voltage value at a middle position after all cell voltage data are sorted from smallest to largest; a represents a linear adjustment parameter for normal values, α>1; Z_{α} represents a linear scaling coefficient for normal values; X_{normal_norm} represents a value of a cell voltage normal value after exponentially decaying;
S34: applying the exponentially increasing function to the outliers, calculated as follows:

$${Z}_{β} = \frac{{x}_{i} - median}{β \cdot IQR} ,$$

$${X}_{outlier \_ norm} = {e}^{{Z}_{β}} ;$$

wherein β represents a linear adjustment parameter for outliers, 0<β<1; Z_{β} represents a linear scaling coefficient for outliers; X_{outlier_norm} represents a value of a cell voltage outlier after exponentially increasing; and
S35: combining the processed normal values and outliers into a new normalized data set.

Further, the calculation of the normal values and the outliers is based on a calculation at a current time point.

Further, the step S4 specifically comprises the following steps:
S41: applying the DTW algorithm, calculating the DTW distance between normalized cell voltage time series at each time point; selecting a normalized median voltage value and comparing the normalized median voltage value with each normalized cell voltage value, thereby achieving battery fault detection;
S42: calculating the standard score of distances between each cell voltage curve and a median voltage curve, expressed as follows:

$$Z = \frac{{X}_{i \_ dtw} - \overline{X}}{σ} ;$$

wherein X_{i_dtw} represents a distance between a voltage curve of cell i and the median voltage curve; X̅ represents an arithmetic mean of distances between all cell voltage curves and the median voltage curve; σ represents a standard deviation of distances between all cell voltage curves and the median voltage curve; Z is the standard score of distances between each cell voltage curve and the median voltage curve; and
S43: based on the obtained standard score of distances between each cell voltage curve and the median voltage curve, establishing a real-time online fault detection model for a traction battery based on voltage curve similarity.

Further, the DTW algorithm in the step S41 has the following process.

Dynamic Time Warping finds a shortest distance path between two sequences through dynamic programming, calculated as follows:

S(i,j)=d(xᵢ, yᵢ)+min(S(i−1, j), S(i, j−1), S(i−1, j−1)),

d(xᵢ, yᵢ)=\sqrt{(xᵢ−yᵢ)²};
wherein S(i,j) represents a Euclidean distance between an i-th element of a sequence X and a j-th element of a sequence Y, and d(xᵢ, yᵢ) represents a distance between an element xᵢ of the sequence X and an element yᵢ of the sequence Y;
each cell voltage sequence is selected as the sequence X, and a median voltage sequence is selected as the sequence Y;
the DTW algorithm traces back from S(i,j) to S(1,1), finding a shortest path between two curves, representing a best match of the two curves on a time axis, thereby capturing similarity between the curves.

Further, in the step S42, an arithmetic mean X̅ bar of distances between all cell voltage curves and the median voltage curve is obtained through the DTW algorithm, expressed as follows:

$$\overline{X} = \frac{1}{N} {\sum }_{i = 1}^{N} {X}_{i \_ dtw}$$

wherein N is a total number of cells;
a standard deviation σ of distances between all cell voltage curves and the median voltage curve is obtained through the DTW algorithm, expressed as follows:

$$σ = \sqrt{\frac{1}{N} {\sum }_{i = 1}^{N} {( {X}_{i \_ dtw} - \overline{X} )}^{2}} .$$

Further, the step S5 specifically comprises the following steps:
S51: setting an appropriate model threshold based on the standard score of distances between each cell voltage curve and the median voltage curve;
S52: determining whether each battery cell has a fault by determining whether a real-time standard score of distances between a cell voltage curve and the median voltage curve exceeds the model threshold, wherein if the standard score exceeds the model threshold, a fault is indicated, and conversely, if the standard score does not exceed the model threshold, no fault is indicated; and
S53: if a fault occurs in the battery module, locating a faulty cell based on the cell voltage where the fault occurs.

Further, the step S6 specifically comprises the following steps:
S61: extracting a physical number of the faulty target battery cell and a time stamp of first triggering the fault, and determining a corresponding fault level by comparing with a preset safety risk matrix; meanwhile, writing a Diagnostic Trouble Code (DTC) into a non-volatile memory (NVM), and locking voltage time series snapshot data collected and buffered by an Analog Front End (AFE) sampling module before and after the fault is triggered;
S62: broadcasting to a Vehicle Control Unit (VCU) and an instrument panel controller through an in-vehicle communication bus, wherein broadcast content comprises a control message of the fault level, so as to drive the instrument panel controller to light up a physical fault indicator and trigger an audible-visual alarm at a vehicle level, and drive the VCU to force the entire vehicle to enter a limp-home mode in which a power output is derated to a preset safety level; wherein the limp-home mode is an operation mode in which a maximum discharge power is limited to a preset ratio of a normal value by a vehicle controller;
S63: dynamically rewriting current charge-discharge control boundaries, lowering a permitted maximum charge-discharge current threshold so as to reduce an electrochemical load of the target battery cell, and issuing a highest-priority drive command to a thermal management actuator, adjusting a coolant pump flow rate or a fan speed so as to start targeted heat dissipation of a physical region of the target battery cell; and
S64: if the fault level reaches a preset safety closed-loop cutoff threshold, the main processor immediately outputs a hardware control level to cut off a coil power supply of a high-voltage contactor or a safety relay in a main high-voltage circuit, forcing the high-voltage contactor to physically disconnect, thereby realizing topological isolation between the battery module and a high-voltage load of the entire vehicle.

Further, in the step S61,
the preset safety risk matrix divides fault levels according to a magnitude of a DTW distance standard score and a number of faulty battery cells:
Level 1 Early Warning: a DTW distance standard score of a single battery cell exceeds a preset first threshold, for example, the first threshold is 3.0 (i.e., exceeding 3 times the standard deviation), monitoring is enhanced, power output is not restricted, and the BMS main control processor marks the battery cell as a “close monitoring required” state;
Level 2 Alarm: a DTW distance standard score of a single or multiple battery cells exceeds a second threshold, for example, the second threshold is 4.0 (i.e., exceeding 4 times the standard deviation), power derating is executed, a maximum discharge power is limited to 70% of a normal value, and a power derating command is sent to the VCU through a Controller Area Network (CAN) bus;
Level 3 Safety: DTW distance standard scores of multiple battery cells exceed a third threshold, for example, the third threshold is 5.0 (i.e., exceeding 5 times the standard deviation), or a total voltage deviation of the battery pack exceeds a preset safety boundary, and high-voltage disconnection is executed;
the BMS main processor records the fault level, a physical number of the faulty cell, the time stamp, and the voltage time series snapshot in the NVM, wherein the DTC comprises a fault type identifier, an occurrence time stamp, and a fault duration counter.

Further, in the step S62:
the control message follows a CAN 2.0B protocol, and a payload of the control message comprises a fault level identifier, a faulty cell number, and a recommended current limit value;
the BMS main processor simultaneously generates the DTC, and sends the DTC to the instrument panel through the CAN bus to trigger a pre-warning visual prompt;
the BMS main processor further uploads fault information to a cloud server through an in-vehicle telematics terminal (T-Box), and pushes a maintenance reminder to a mobile terminal.

Further, in the steps S63 and S64, the BMS main processor further performs the following operations:
sending a hardware register rewrite command to an AFE chip of a designated channel through an isolated daisy-chain communication bus (isoSPI), forcibly turning off an internal or external balancing MOSFET switch corresponding to the faulty cell, and cutting off a discharge resistor path;
rewriting a PWM output duty cycle of a thermal management controller, pulling up a rotation speed of an electric liquid cooling pump to full load, or adjusting an opening of an electronic thermostat valve, so as to directionally divert a cooling medium to a module where the faulty cell is located;
if the electric vehicle is in a charging state, sending a charging current limit command to an on-board charger (OBC) through the CAN bus, so as to reduce a charging current to below a safety threshold; if the electric vehicle is in a non-charging state, i.e., a driving state, sending a power limit command to a motor controller through the CAN bus, so as to limit a maximum driving power of the entire vehicle to a preset ratio of a normal value;
when the fault level reaches Level 3 Safety, a high-side driver chip or a low-side driver chip of the BMS main processor changes a GPIO pin level state, so that a coil of the high-voltage contactor loses power, an armature of the contactor springs open under the action of a mechanical spring, and a physical air gap is formed between a positive busbar and a negative busbar of the battery pack and a high-voltage load, thoroughly cutting off a high-voltage bus current by means of the physical air gap.

The method of the present application operates in an on-board battery fault detection system, the system comprising:
(1) the battery module, comprising a plurality of battery cells connected in series and/or in parallel;
(2) the Analog Front End (AFE) sampling module, electrically connected to each battery cell in the battery module through sampling wires, internally integrating a multi-channel differential analog-to-digital converter (ADC), and synchronously collecting voltage signals of each battery cell at a fixed sampling period;
(3) the BMS main control processor, communicatively connected to the AFE sampling module through an isolated communication bus, wherein a non-volatile memory stores a fault detection algorithm program, and the BMS main control processor is configured to execute the fault detection method, determine whether each battery cell has a fault and determine a fault level of the battery cell;
(4) a CAN communication module, connected to the BMS main control processor, and broadcasting a fault level control message to the VCU and an instrument panel according to the fault level;
(5) an alarm module, connected to the BMS main control processor, and lighting up a fault indicator and triggering an audible-visual alarm according to the fault level; and
(6) an actuator, connected to the BMS main control processor, comprising a balancing circuit switch array, a thermal management actuator, and a high-voltage relay drive circuit, and executing protection operations according to the fault level, wherein the protection operations comprise turning off a balancing branch, lowering a maximum current threshold, driving the thermal management actuator to execute targeted heat dissipation, and cutting off a high-voltage contactor so as to physically disconnect an electrical connection between the battery pack and a high-voltage load.

Further, the AFE sampling module comprises an AFE chip, wherein the AFE chip is an automotive-grade chip having a multi-channel differential ADC function, and each sampling wire is connected to a positive terminal and a negative terminal of a corresponding battery cell;
the AFE chip reports sampling data to the BMS main control processor through an isolated daisy-chain communication bus (isoSPI), the BMS main control processor receives the sampling data, and adds a global time stamp to each piece of cell voltage data so as to realize time alignment.

Further, the BMS main control processor is a vehicle-mounted MCU running a real-time operating system conforming to an AUTOSAR standard;
the fault detection algorithm program is stored in a FLASH memory of the BMS main control processor in an embedded form, and is periodically executed at a fixed detection period under the real-time operating system;
the BMS main control processor is further configured to store a faulty cell number, a fault occurrence time, and a detection time difference in the non-volatile memory after determining the fault.

Further, the actuator comprises:
a balancing circuit switch array, comprising a balancing MOSFET connected in parallel with each battery cell, wherein the BMS main control processor sends a register rewrite command to the AFE chip through the isolated daisy-chain communication bus (isoSPI) so as to control on/off of the balancing MOSFET;
a thermal management actuator, comprising a liquid cooling pump, a cooling fan, a PWM drive circuit, and an electronic thermostat, wherein the BMS main control processor controls a rotation speed of the liquid cooling pump and the cooling fan by rewriting a PWM duty cycle, and controls a flow rate of a cooling medium by adjusting an opening of the electronic thermostat;
a high-voltage relay drive circuit, comprising a high-side driver chip or a low-side driver chip, wherein the BMS main control processor controls the high-side driver chip or the low-side driver chip by changing a GPIO level output, so that a coil of the high-voltage contactor loses power, an armature springs open, and a physical air gap is formed between a positive busbar and a negative busbar of the battery pack and a high-voltage load.

Further, the BMS main control processor is further configured to:
after determining that a battery cell has a fault, extract a physical number of a faulty target battery cell and a time stamp of first triggering the fault, and determine a corresponding fault level by comparing with a preset safety risk matrix; wherein the preset safety risk matrix divides fault levels according to a magnitude of a DTW distance standard score and a number of faulty battery cells:
Level 1 Early Warning: a DTW distance standard score of a single battery cell exceeds a preset first threshold, monitoring is enhanced, and power output is not restricted;
Level 2 Alarm: DTW distance standard scores of a single or multiple battery cells exceed a second threshold, power derating is executed, and a maximum discharge power is limited to 70% of a normal value;
Level 3 Safety: DTW distance standard scores of multiple battery cells exceed a third threshold, or a total voltage deviation of the battery pack exceeds a preset safety boundary, and high-voltage disconnection is executed; meanwhile, the BMS main control processor writes the DTC in the non-volatile memory, and locks voltage time series snapshot data collected and buffered by the AFE sampling module before and after the fault is triggered; wherein the DTC comprises a fault type identifier, an occurrence time stamp, and a fault duration counter.

Further, the CAN communication module is further configured to:
broadcast a fault level control message to the VCU and an instrument panel controller through an in-vehicle communication bus according to the fault level determined by the BMS main control processor, wherein the control message follows a CAN 2.0B protocol and comprises a fault level identifier, a faulty cell number, and a recommended current limit value;
the BMS main control processor is further configured to:
drive the instrument panel controller to light up a physical fault indicator, and trigger an audible-visual alarm;
drive the VCU to force the entire vehicle to enter a limp-home mode, wherein the limp-home mode is an operation mode in which a maximum discharge power is limited to a preset ratio of a normal value by a vehicle controller;
if the electric vehicle is in a charging state, send a charging current limit command to an on-board charger (OBC) through the CAN bus, so as to reduce a charging current to below a safety threshold;
if the electric vehicle is in a non-charging state, i.e., a driving state, send a power limit command to a motor controller through the CAN bus, so as to limit a maximum driving power of the entire vehicle to a preset ratio of a normal value;
if the fault level reaches a preset safety closed-loop cutoff threshold, the BMS main control processor changes a GPIO pin level state through a high-side driver chip or a low-side driver chip, so that a coil of the high-voltage contactor loses power, an armature springs open, and a physical air gap is formed between a positive busbar and a negative busbar of the battery module and a high-voltage load.

Based on the above system architecture, the method of the present application operates periodically at a fixed detection period in the BMS main control processor. Within each detection period, the BMS main control processor receives voltage time series data of each battery cell collected by the AFE sampling module through the isolated communication bus, sequentially executes Kalman filtering preprocessing, quantile and exponentially weighted adaptive normalization processing, DTW distance calculation and standard score calculation, and threshold-based fault determination, and generates fault control signals after determining a fault and sends the fault control signals to the VCU and the actuator through the CAN communication module, thereby forming a complete closed loop from physical signal collection, data processing, fault diagnosis to physical protection control.

The beneficial effects of the present application are as follows.

The proposed quantile normalization method performs standardization processing on battery measurement data based on the median and interquartile range, which can significantly improve feature robustness to outliers, avoid interference of extreme data on fault identification results, and enhance stability and accuracy in the data preprocessing stage.

An exponential enhancement normalization strategy is introduced, which applies higher normalization weights to suspected outliers outside statistical boundaries, so that potential early slight faults are effectively amplified in the standardized feature space, thereby improving the identifiability of weak anomalies and facilitating fine-grained fault detection.

The method proposed by the present application does not rely on a large number of historical samples or complex models, is suitable for online fault detection scenarios during electric vehicle operation, has good real-time performance and engineering deployability, can accurately locate early anomalies at the cell level, and enhances the overall safety guarantee capability of the system.

Other advantages, objectives, and features of the present application will be set forth in part in the following description, and in part will become apparent to those skilled in the art upon examination of the following description, or may be learned from practice of the present application. The objectives and other advantages of the present application may be realized and attained through the following specification.

### BRIEF DESCRIPTION OF THE DRAWINGS

To make the objectives, technical solutions, and advantages of the present application clearer, the present application will be described in detail below with reference to the accompanying drawings, wherein:

FIG. 1 is an overall method flowchart of the present application;

FIG. 2 is an algorithm framework diagram of an embodiment;

FIG. 3 shows cell voltage curves of normal cells and faulty cells in an embodiment;

FIG. 4 shows cell voltage Kalman filtering curves of normal cells and faulty cells in an embodiment;

FIG. 5 shows cell voltage normalization curves of normal cells and faulty cells in an embodiment;

FIG. 6 shows DTW fault detection results of normal cells and faulty cells in an embodiment; and

FIG. 7 is a hardware architecture schematic diagram of the battery fault detection system according to an embodiment of the present application.

### DETAILED DESCRIPTION OF THE EMBODIMENTS

The embodiments of the present application will be described below through specific examples. Those skilled in the art can easily understand other advantages and effects of the present application from the contents disclosed in the present specification. The present application may also be implemented or applied through other different specific embodiments, and various details in the present specification may be modified or changed based on different perspectives and applications without departing from the spirit of the present application. It should be noted that the drawings provided in the following embodiments only illustrate the basic concept of the present application in a schematic manner, and in the case of no conflict, the following embodiments and features in the embodiments may be combined with each other.

It should be noted that the drawings provided in the following embodiments only illustrate the basic concept of the present application in a schematic manner, and therefore the drawings only show components related to the present application rather than being drawn according to the number, shape, and dimensions of components during actual implementation. The form, number, and proportion of components during actual implementation may be arbitrarily changed, and the component layout form may also be more complex.

In the following description, numerous details are discussed to provide a more thorough explanation of the embodiments of the present application. However, it will be apparent to those skilled in the art that the embodiments of the present application may be practiced without these specific details. In other embodiments, well-known structures and devices are shown in block diagram form rather than in detail so as not to obscure the embodiments of the present application.

### Embodiment 1

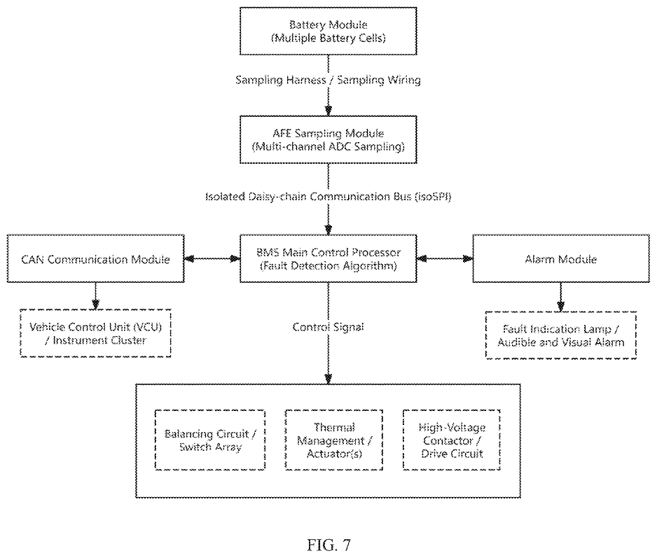

This embodiment provides a battery fault detection method based on quantile and exponentially weighted adaptive normalization, wherein the method operates in an on-board battery fault detection system. Referring to FIG. 7, the battery fault detection system has a hardware architecture comprising a battery module, an Analog Front End (AFE) sampling module, a Battery Management System (BMS) main control processor, a memory, a CAN communication module, an alarm module, and an actuator. The system architecture is described as follows:
(1) Battery module: composed of 96 NCM ternary lithium-ion battery cells connected in series, divided into 6 battery modules, each module containing 16 battery cells. A rated voltage range of the battery pack is 300V to 800V. Each battery module is configured with a Cell Supervisory Circuit (CSC) sub-control board, wherein a core MCU of the CSC sub-control board is an NXP S32K344 chip, with a main frequency of 160 MHz, built-in RAM 512 KB, FLASH 4 MB, running a real-time operating system (RTOS) conforming to the AUTOSAR standard. Each CSC sub-control board communicates with a BMS main board through a high-speed CAN bus and periodically reports voltage data of each battery cell.
(2) Analog Front End (AFE) sampling module: a MAX14921 type 16-channel synchronous sampling AFE chip is adopted, which internally integrates a multi-channel differential analog-to-digital converter (ADC), with a sampling accuracy of +0.5 mV and an ADC resolution of 14 bits. Each MAX14921 chip manages 16 battery cells in one battery module, and a positive terminal and a negative terminal of each battery cell are respectively connected to a differential input channel of the AFE chip through sampling wires. The AFE chip performs synchronous sampling on terminal voltages of each battery cell at a fixed sampling period of 200 ms, and transmits sampling data to an MCU of the corresponding CSC sub-control board in a differential signal manner through an isolated daisy-chain communication bus (isoSPI). After receiving the sampling data, the CSC sub-control board adds a global time stamp to voltage data of each battery cell to realize time alignment of data from each channel, and then reports multi-channel voltage time series data containing precise time information to the BMS main board through the CAN bus.

As a variant, the AFE sampling module may also adopt other automotive-grade chips having multi-channel differential ADC functions as substitutes, for example, MAX14920, LTC6811, BQ76PL455A, or MC33771 chips. A sampling period of the AFE chip may be set according to actual needs, for example, 50 ms, 100 ms, 200 ms, 500 ms, or 1000 ms, and an ADC resolution may be selected from 12 bits to 16 bits. A communication manner between the AFE chip and the BMS main control processor may also adopt an isolated CAN bus as a substitute for the isoSPI daisy-chain communication bus.
(3) BMS main control processor: an NXP S32K344 vehicle-mounted MCU is adopted, with a main frequency of 160 MHz, RAM 512 KB, FLASH 4 MB, running a real-time operating system (RTOS) conforming to the AUTOSAR standard. The fault detection algorithm program (including a Kalman filtering module, a quantile and exponentially weighted normalization module, a DTW distance calculation module, a standard score calculation module, and a fault determination module) is stored in a FLASH memory of the BMS main control processor in an embedded C code form, and is periodically scheduled and executed by the RTOS at a fixed detection period of 200 ms. Within each detection period, the BMS main control processor executes the following sequence of operations: receiving voltage time series data of 96 battery cells reported by 6 CSC sub-control boards through the CAN bus; sequentially executing Kalman filtering, quantile and exponentially weighted adaptive normalization, DTW distance calculation, and standard score calculation; determining whether a fault exists according to the standard score; if it is determined that a fault exists, generating a fault control signal, and sending the fault control signal to the VCU and/or the actuator through the CAN communication module.

As a variant, the BMS main control processor may also adopt other vehicle-mounted MCUs as substitutes, for example, STMicroelectronics STM32 series (such as STM32F4, STM32H7), Infineon AURIX TC3xx series, Renesas RH850 series, and the like. The real-time operating system may also adopt other embedded RTOS conforming to functional safety standards (such as ISO 26262), for example, FreeRTOS, OSEK/VDX compatible OS, or SAFERTOS.
(4) Memory: used for storing fault detection model parameters, including quantile thresholds, coefficients of the exponential decay/growth functions, DTW distance thresholds, standard score thresholds, and the like, as well as fault log history data. Voltage time series data, intermediate calculation results, and fault determination results for each sampling period may all be stored in a RAM for real-time access.
(5) CAN communication module: supporting the CAN 2.0B protocol, with a communication rate of 500 kbps. The BMS main control processor periodically broadcasts fault level control messages to the Vehicle Control Unit (VCU) and the instrument panel controller through the CAN communication module. The control messages adopt a standard frame format (11-bit identifier) or an extended frame format (29-bit identifier), and a message payload includes:
a fault level identifier: 1 byte, with values 0x01-0x03 respectively corresponding to Level 1 Early Warning, Level 2 Alarm, and Level 3 Safety;
a faulty cell physical number: 1 byte, with values 0x00-0x5F corresponding to the 1st to 96th cells;
and a recommended current limit value: 2 bytes, in units of 0.1 A.

In a fault state, the BMS main control processor broadcasts the control message at a rate of once every 100 ms until the fault is eliminated or the system is powered down.
(6) Alarm module and actuator: when the BMS main control processor determines that a certain battery cell has a fault, on one hand, it uploads fault information to a cloud server through an in-vehicle telematics terminal (T-Box) via 4G/5G mobile communication. The fault information includes a fault level, a faulty cell number, a fault time stamp, and voltage time series snapshot data of 256 sampling points (approximately 51.2 seconds) before and after the fault trigger. After receiving the fault information, a cloud platform pushes a maintenance reminder notification to an owner's mobile APP via a mobile communication network, the notification content including a fault description, recommended maintenance measures, and information of the nearest authorized maintenance station.

On the other hand, the BMS directly sends control commands to the actuator. The actuator comprises three subsystems: a balancing circuit switch array, a thermal management actuator, and a high-voltage relay drive circuit:
(a) Balancing circuit switch array: comprising an internal balancing MOSFET and/or an external balancing MOSFET connected in parallel with each battery cell. In a normal working state, the balancing MOSFET is periodically turned on according to a BMS balancing strategy to consume excess charge of cells with higher charge. When the BMS main control processor detects that a specific battery cell has a fault, it sends a hardware register rewrite command to the AFE chip (MAX14921) of the corresponding channel through the isoSPI daisy-chain communication bus, forcibly setting a gate drive signal of the balancing MOSFET to a low level, thereby permanently turning off the balancing branch of the faulty cell.
(b) Thermal management actuator: comprising an electric liquid cooling pump, a cooling fan, a PWM drive circuit, and an electronic thermostat. The BMS main control processor increases a cooling liquid flow and an air convection heat dissipation capability by rewriting a PWM output duty cycle, for example, increasing a liquid cooling pump PWM duty cycle from 50% during normal operation to 100%, and increasing a cooling fan PWM duty cycle from 30% to 100%; meanwhile, adjusting a valve opening of the electronic thermostat through the CAN bus or a PWM signal, so as to directionally and preferentially supply the cooling medium to a module area where the faulty cell is located.
(c) High-voltage relay drive circuit: comprising a high-side driver chip (such as Infineon BTS500xx series) and/or a low-side driver chip. When the BMS main control processor determines that the fault level reaches Level 3 Safety, it controls the high-side driver chip or the low-side driver chip to turn off an output by changing an output level of a corresponding GPIO pin, for example, pulling down a GPIO pin originally maintaining a logic high level (3.3V) to a logic low level (0V), so that coils of a main positive high-voltage contactor and a main negative high-voltage contactor lose power. After the coils lose power, armatures of the contactors spring open under the action of internal mechanical reset springs, and a physical air gap is formed between positive and negative busbars of the battery pack and a high-voltage load of the entire vehicle, realizing thorough electrical isolation and topological disconnection. A spacing of the physical air gap ensures that arc breakdown will not occur even under the entire vehicle high-voltage system (300V-800V).

As a variant, the MOSFET in the balancing circuit switch array may adopt an N-channel enhancement-mode power MOSFET, for example, IRF3205, IRLZ44N, and other models; other types of solid-state switching devices may also be adopted, for example, IGBT, silicon carbide (SiC) MOSFET, and the like. The cooling medium of the thermal management actuator is not limited to a liquid cooling manner, and may also adopt an air cooling manner or a direct refrigerant cooling manner. The contactor in the high-voltage relay drive circuit may adopt a single-coil or dual-coil electromagnetic relay, a solid-state relay (SSR), or a smart high-voltage contactor module having a pre-charge function.

The above system forms a complete detection and control closed loop: the AFE sampling module collects voltage physical signals of each battery cell→reports to the BMS main control processor through the isoSPI/CAN bus→the BMS main control processor executes filtering, normalization, DTW calculation, and fault determination→generates control signals after determining a fault→sends control messages to the VCU through the CAN bus and controls the actuator through GPIO→the actuator completes balancing turn-off, thermal management enhancement, and/or high-voltage disconnection. This closed loop extends fault detection from an information processing level to a physical control level, ensuring safety of the battery pack in a fault state.

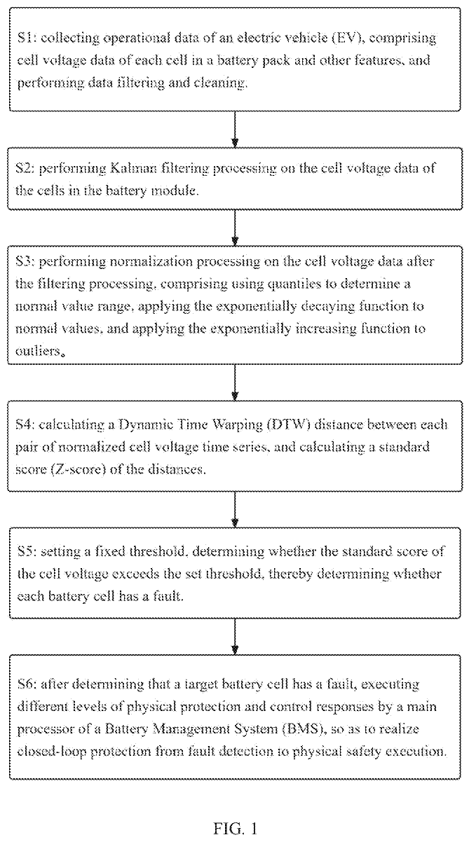

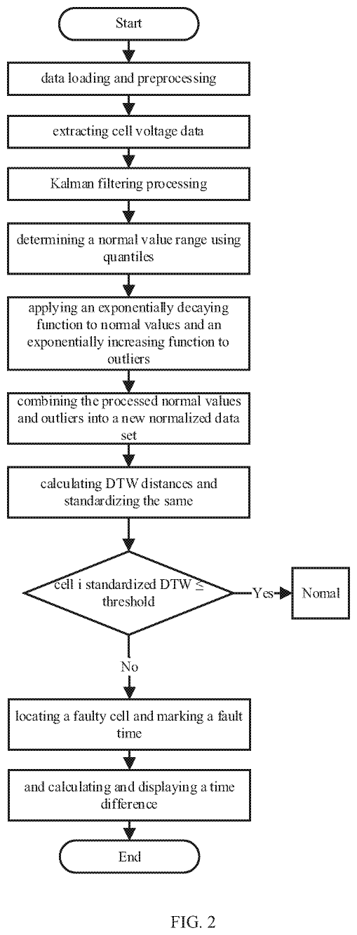

As shown in FIGS. 1-2, the present application provides a battery fault detection method based on quantile and exponentially weighted adaptive normalization, which is specifically divided into the following steps:
Step S1: collecting operational data of an electric vehicle (EV), comprising cell voltage data of each cell in a battery pack and other features, and performing data filtering and cleaning.

Specifically, a positive electrode and a negative electrode of each battery cell are respectively connected to multi-channel differential input terminals of an analog front end voltage sampling chip through battery pack sampling wires. The AFE chip performs synchronous sampling on terminal voltages of each battery cell at a fixed sampling period, and an internally integrated ADC module provides a 12-bit to 16-bit resolution. Collected voltage digital quantities are added with global time stamps synchronously acquired from the BMS main controller by an MCU of a CSC module, and are reported to the BMS main control processor through an isolated CAN bus, thereby completing collection of battery cell voltage time series data with precise time alignment information.

Specifically comprising the following steps:
Step S11: collecting normal operational data of a certain electric vehicle (EV), comprising a total voltage, each cell voltage, time and other parameters, and a BMS alarm signal;
Step S12: performing data processing and data cleaning on the cell voltage, and filling missing values of the data; wherein data cleaning removes rows where a total voltage is 0, and data missing value filling may adopt an adjacent cell average value interpolation method;
Step S13: establishing a traction battery operational database based on the collected operational data of the battery pack and each battery cell.
Step S2: performing Kalman filtering processing on the cell voltage data of the battery cells, specifically comprising the following steps:
Step S21: determining an initial state estimation and an estimation error covariance based on the processed cell voltage data;
Step S22: using a mean and a variance of the first few data points as the initial state estimation, predicting a state at a current time point by using a state estimation at a previous time point, and updating the estimation error covariance;
Step S23: calculating a Kalman gain based on a current measurement value, correcting the predicted state to obtain a more precise estimation, and updating the estimation error covariance;
Step S24: performing filtering processing on each cell voltage time series, wherein a filtering process outputs a smoothed and stable data sequence at each time point.
Step S3: performing normalization processing based on the cell voltage data after the filtering processing, comprising using quantiles to determine a normal value range, applying the exponentially decaying function to normal values, and applying the exponentially increasing function to outliers, specifically comprising the following steps:
Step S31: using quartiles to determine the normal value range, a lower limit of the normal value range being calculated as follows:

Q₁−1.5·IQR;
an upper limit of the normal value range being calculated as follows:

Q₃+1.5·IQR;
wherein Q₁ represents a first quartile, which is a 25th percentile of the cell voltage data; Q₃ represents a third quartile, which is a 75th percentile of the cell voltage data; IQR is a difference between the third quartile (Q₃) and the first quartile (Q₁) in the cell voltage data set, expressed as follows:

IQR=Q₃−Q₁;
Step S32: based on the determined normal value range, determining normal values and outliers of the cell voltage, wherein cell voltage data within the upper and lower limit interval of the normal value range are normal values, and cell voltage data outside the upper and lower limit interval of the normal value range are outliers;
Step S33: applying the exponentially decaying function to the normal values, calculated as follows:

$${Z}_{α} = \frac{{x}_{i} - median}{α \cdot IQR} ,$$

$${X}_{normal \_ norm} = {e}^{- {Z}_{α}} ;$$

wherein Xᵢ represents a voltage value of each cell i; median represents a median of cell voltages, which is a cell voltage value at a middle position after all cell voltage data are sorted from smallest to largest; a represents a linear adjustment parameter for normal values, α>1; Za represents a linear scaling coefficient for normal values; X_{normal_norm} represents a value of a cell voltage normal value after exponentially decaying.
Step S34: applying the exponentially increasing function to the outliers, calculated as follows:

$${Z}_{β} = \frac{{x}_{i} - median}{β \cdot IQR} ,$$

$${X}_{outlier \_ norm} = {e}^{{Z}_{β}} ;$$

wherein β represents a linear adjustment parameter for outliers, 0<β<1; Z_{β} represents a linear scaling coefficient for outliers; X_{outlier_norm} represents a value of a cell voltage outlier after exponentially increasing.
Step S35: combining the processed normal values and outliers into a new normalized data set.

It should be noted that the calculation of the normal values and the outliers is based on a calculation at a current time point, including determination of the normal value range, application of the exponentially decaying function to the normal values, and application of the exponentially increasing function to the outliers.
Step S4: calculating a DTW distance between each pair of normalized cell voltage time series, and calculating a standard score of the distances, specifically comprising the following steps:
Step S41: applying the Dynamic Time Warping (DTW) algorithm, calculating the DTW distance between normalized cell voltage time series at each time point; wherein, in order to reduce an influence of abnormal battery cells on an average voltage, a normalized median voltage value is selected and compared with each normalized cell voltage value, thereby achieving battery fault detection. The Dynamic Time Warping algorithm has the following process:

Dynamic Time Warping finds a shortest distance path between two sequences through dynamic programming, calculated as follows:

S(i,j)=d(xᵢ, yᵢ)+min(S(i−1, j), S(i, j−1), S(i−1, j−1)),

d(xᵢ, yᵢ)=\sqrt{(xᵢ−yᵢ)²};
wherein S(i,j) represents a distance between an i-th element of a sequence X and a j-th element of a sequence Y, generally using a Euclidean distance, and d(xᵢ, yᵢ) represents a distance between an element xᵢ of the sequence X and an element yᵢ of the sequence Y.

Typically, each cell voltage sequence is selected as the sequence X, and a median voltage sequence is selected as the sequence Y.

Dynamic Time Warping traces back from S(i,j) to S(1,1), finding a shortest path between two curves, representing a best match of the two curves on a time axis, thereby capturing similarity between the curves.
Step S42: calculating the standard score (Z-score) of distances between each cell voltage curve and the median voltage curve, expressed as follows:

$$Z = \frac{{X}_{i \_ dtw} - \overline{X}}{σ} ;$$

wherein X_{i_dtw} represents a distance between a voltage curve of cell i and the median voltage curve; X̅ represents an arithmetic mean of distances between all cell voltage curves and the median voltage curve; σ represents a standard deviation of distances between all cell voltage curves and the median voltage curve; Z is the standard score of distances between each cell voltage curve and the median voltage curve.

Wherein, the arithmetic mean X̅ of distances between all cell voltage curves and the median voltage curve is obtained through the Dynamic Time Warping algorithm, expressed as follows:

$$\overline{X} = \frac{1}{N} {\sum }_{i = 1}^{N} {X}_{i \_ dtw} ;$$

wherein N is a total number of cells.

The standard deviation σ of distances between all cell voltage curves and the median voltage curve is obtained through the Dynamic Time Warping algorithm, expressed as follows:

$$σ = \sqrt{\frac{1}{N} {\sum }_{i = 1}^{N} {( {X}_{i \_ dtw} - \overline{X} )}^{2}} .$$

Step S43: based on the obtained standard score of distances between each cell voltage curve and the median voltage curve, establishing a real-time online fault detection model for a traction battery based on voltage curve similarity.

The fault detection model is stored in the non-volatile memory of the BMS main control processor in an embedded form, and includes algorithm program codes of Kalman filtering, quantile and exponentially weighted normalization, DTW distance calculation, fault determination, and the like, as well as a configurable model parameter table. At runtime, the model is periodically executed under a framework of the RTOS of the BMS. For each sampling period or each sliding time window update, the BMS main control processor sequentially invokes Kalman filtering, normalization processing, DTW distance calculation, and standard score calculation, completes fault state determination of each battery cell, and generates fault control signals in real time according to an update result, such as charging limit commands, power derating commands, balancing branch control signals, alarm frames, or DTC fault codes, and sends the fault control signals to actuators of the entire vehicle through the CAN bus.
Step S5: setting a fixed threshold, and determining whether each battery cell has a fault according to whether the standard score of the cell voltage exceeds the set threshold, specifically comprising the following steps:
Step S51: setting an appropriate model threshold based on the standard score of distances between each cell voltage curve and the median voltage curve;
Step S52: determining whether each battery cell has a fault by determining whether a real-time standard score of distances between a cell voltage curve and the median voltage curve exceeds the model threshold, wherein if the standard score exceeds the model threshold, a fault is indicated, and conversely, if the standard score does not exceed the model threshold, no fault is indicated;
Step S53: if a fault occurs in the battery, locating a faulty cell based on the cell voltage where the fault occurs.

Wherein, locating the faulty cell comprises locating a faulty cell number and a time when the faulty cell has a fault, and calculating and displaying a time difference between a fault detection time and a warning time.

After completing the faulty cell locating, the model generates a diagnostic report comprising a faulty cell number, a fault occurrence time, a detection time difference, and a fault level, which is stored in the non-volatile memory of the BMS and sent to the VCU through the CAN bus; meanwhile, the BMS main controller executes the following measures according to the fault level: turning off or adjusting a balancing branch of the corresponding cell, reducing a participation weight of the cell in SOC estimation, increasing a cooling intensity of a module where the faulty cell is located, sending current limiting and power derating commands to the on-board charger and the motor controller through the CAN bus, triggering an instrument alarm and generating a DTC fault code conforming to the ISO 15031 standard, and disconnecting a high-voltage relay in a critical fault; in particular, when the detection time difference indicates that the present method has detected an anomaly significantly earlier than a BMS conventional alarm, the BMS activates a preventive protection strategy, reducing a charge-discharge rate in advance, issuing a driver warning, and recording an early fault log, thereby effectively avoiding a battery thermal runaway risk and curbing capacity degradation expansion.
Step S6: the BMS main control processor, after determining that a target battery cell has a fault, executes the following multi-level closed-loop physical protection and control responses:
S61: extracting a physical number of the faulty cell and a time stamp of first triggering the fault, determining a fault level (Level 1 Early Warning/Level 2 Alarm/Level 3 Safety) by comparing a magnitude of the DTW standard score and a number of faulty cells with a safety risk matrix; meanwhile, writing a DTC fault code in the NVM and locking voltage time series snapshot data before and after the fault;
S62: broadcasting a fault level control message to the VCU and an instrument panel at a period of every 100 ms through a CAN 2.0B bus, lighting up a fault indicator and triggering an audible-visual alarm, and forcing the entire vehicle to enter a limp-home mode: limiting a maximum discharge power to 70% of a normal value; meanwhile uploading fault information to a cloud server through a T-Box via 4G/5G and pushing a maintenance reminder to a mobile terminal;
S63: lowering a maximum charge-discharge current threshold, limiting the threshold to 30% of a normal value, rewriting a PWM duty cycle to increase a liquid cooling pump rotation speed to full load, and directionally diverting a cooling medium to a module where the faulty cell is located through an electronic thermostat; if the vehicle is in a charging state, limiting an OBC charging current through the CAN bus; if the vehicle is in a driving state, limiting a motor controller drive power to 30% of a normal value;
S64: if the fault level reaches Level 3 Safety, the BMS main control processor changes a level state through GPIO so that a coil of a high-voltage contactor loses power, an armature of the contactor springs open under the action of a spring, and a physical air gap is formed between the battery pack and a high-voltage load, realizing topological isolation.

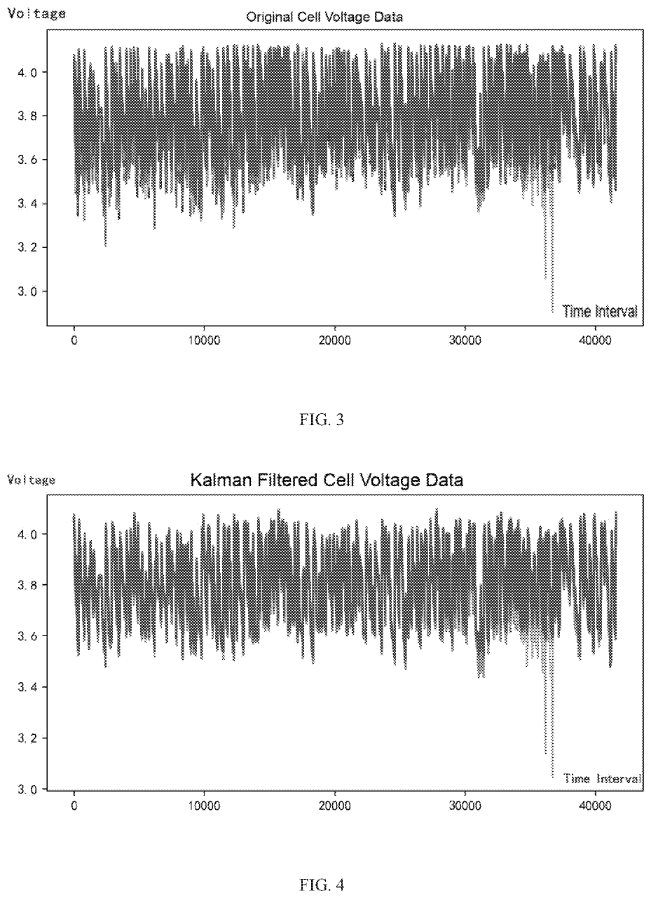

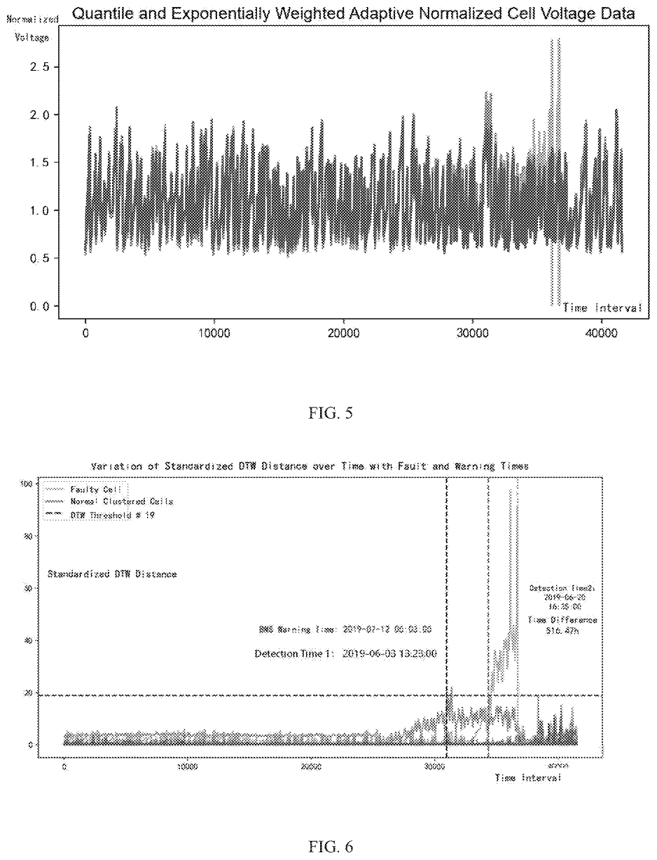

To demonstrate the effectiveness of the present application, operational data of a faulty vehicle was prepared, wherein one battery cell experienced capacity degradation, and one battery cell had a fault detected by the BMS alarm. FIG. 3 shows cell voltage curves of normal cells and faulty cells of the faulty vehicle battery. Kalman filtering and normalization processing were performed on the data. FIG. 4 shows cell voltage Kalman filtering curves of normal cells and faulty cells of the faulty vehicle battery, and FIG. 5 shows cell voltage normalization curves of normal cells and faulty cells of the faulty vehicle battery. DTW algorithm processing was performed on the normalized data, and a standard score detection threshold was set to 19. FIG. 6 shows DTW fault detection results of normal cells and faulty cells of the faulty vehicle battery. No false alarm occurred for normal cells, and a fault was detected earlier than the BMS alarm time. Therefore, the present application can effectively suppress interference of outliers on the overall distribution and enhance the expression of potential weak anomaly information, can better realize real-time fault detection of electric vehicle traction batteries, and accurately locate faulty cells.

### Embodiment 2

An electronic device, comprising a memory and a processor;
the memory is used for storing a computer program; the memory is specifically a non-volatile memory (NVM) of the BMS main control processor, used for permanently storing the fault detection algorithm program and model operating parameters.

The processor is used for, when executing the computer program, implementing the method according to Embodiment 1. The processor is specifically the BMS main control processor (for example, an NXP S32K344 vehicle-mounted MCU), which periodically executes the fault detection algorithm program at a fixed period of 200 ms under scheduling of an AUTOSAR RTOS.

### Embodiment 3

A computer-readable storage medium, wherein the storage medium stores a computer program thereon, and when the computer program is executed by a processor, the method according to Embodiment 1 is implemented.

The computer-readable storage medium is a non-transitory storage medium, specifically a FLASH memory of the BMS main control processor. The computer program comprises program instructions that cause the BMS main control processor to execute the following operations: receiving battery cell voltage sampling signals from the AFE sampling module; executing Kalman filtering, quantile and exponentially weighted adaptive normalization, DTW distance calculation, and standard score calculation; determining a fault based on a threshold; identifying a faulty cell; and generating control commands to limit charge-discharge power, control a thermal management actuator, and/or disconnect a high-voltage contactor through the CAN bus.

### Embodiment 4

A computer program product, comprising a computer program, wherein when the computer program is executed by a processor, the method according to Embodiment 1 is implemented.

### Embodiment 5

This embodiment takes a new energy passenger vehicle equipped with a ternary lithium-ion battery pack as an example to illustrate the online operating effect of the method of the present application in a real vehicle BMS.

The battery pack of the vehicle is composed of 96 NCM ternary lithium-ion battery cells connected in series, divided into 6 battery modules, each module containing 16 battery cells. The BMS adopts a distributed architecture: each module is provided with a CSC sub-control board, with an MCU being an NXP S32K344 chip, a main frequency of 160 MHz, RAM 512 KB, running an AUTOSAR RTOS; each CSC communicates with a BMS main board through a high-speed CAN bus (500 kbps) and reports data. The AFE chip adopts a MAX14921 type 16-channel synchronous sampling chip, with a sampling accuracy of +0.5 mV, a sampling period of 200 ms, and a sliding window length N=128 sampling points. The above system operates according to the closed-loop process described above.

During long-term road testing of the vehicle, one battery cell exhibited a slight capacity degradation anomaly. At this stage, the conventional threshold alarm mechanism of the BMS had not yet triggered any alarm, but the fault detection algorithm of the present application was continuously running in the BMS main control processor (the above NXP S32K344 MCU) and performed the following operations:
Step 1 (Data Collection): The BMS main control processor receives voltage data of 96 battery cells reported by each CSC sub-control board through the CAN bus, forming 96 voltage time series;
Step 2 (Kalman Filtering): Kalman filtering is performed on each voltage time series one by one to filter out sampling noise and instantaneous anomaly jumps;
Step 3 (Quantile Exponential Enhancement Normalization): Quartile boundaries of each cell voltage data are calculated, exponential decay (α=0.5) is applied to normal values, and exponential growth (β=2.0) is applied to outliers, forming a normalized data set;
Step 4 (DTW Distance and Standard Score Calculation): DTW distances between each cell voltage sequence and a median voltage sequence are calculated with a window length N=128, and standard scores of 96 battery cells are calculated accordingly;
Step 5 (Fault Determination): It is found that the standard score of the battery cell with capacity degradation exceeds a preset threshold T=3.0, i.e., exceeding 3 times the standard deviation, while the BMS conventional alarm mechanism did not issue any fault alarm at this time point. Subsequent analysis confirmed that the method of the present application detected this anomaly approximately 60 seconds earlier than the BMS conventional alarm;
Step 6 (Multi-level Closed-loop Protection and Control):

After determining the fault, the BMS main control processor executes the following:
recording a faulty cell number, a fault occurrence time, and a detection time difference in a fault log;
generating a DTC fault code, and sending the DTC fault code to the instrument panel through the CAN bus to trigger a visual prompt of “please check the battery system”;
sending a power limit request to the VCU through the CAN bus, limiting a maximum discharge power of the entire vehicle to 70% of a normal value;
activating a thermal management differentiation strategy, increasing a cooling fan rotation speed of a module where the faulty cell is located;
if the vehicle is in an AC slow charging state, sending a charging current limit command to the OBC through the CAN bus, reducing a charging current from 32 A to 16 A;
uploading fault information to a cloud server through the on-board T-Box, and pushing a maintenance reminder of “it is recommended to visit a service center as soon as possible” to the owner's mobile App.

At this point, since an early anomaly of the battery pack is detected in a timely manner, the preventive measures taken by the BMS effectively curbed further expansion of the cell voltage deviation. Subsequent maintenance inspection confirmed that the faulty cell was an early capacity degradation caused by a manufacturing consistency defect.

This embodiment demonstrates that the method of the present application can operate in real time under limited hardware resources of an on-board BMS, accurately identify weak faults, transform diagnostic results into actual control of battery charge-discharge processes, thermal management processes, and alarm processes, and form closed-loop protection.

In the above embodiments, reference to “this embodiment” in the specification indicates that a particular feature, structure, or characteristic described in connection with the embodiment is included in at least some embodiments, but not necessarily all embodiments. Multiple occurrences of “this embodiment” do not necessarily all refer to the same embodiment.

In the above embodiments, although the present application has been described in connection with specific embodiments thereof, many substitutions, modifications, and variations of these embodiments will be apparent to those of ordinary skill in the art based on the foregoing description. For example, other storage structures (such as dynamic RAM (DRAM)) may use the discussed embodiments. The embodiments of the present application are intended to cover all such substitutions, modifications, and variations falling within the broad scope of the appended claims.

In the above embodiments, the computer-readable storage medium will be understood by those of ordinary skill in the art that: implementation of all or part of the steps of the above method embodiments may be accomplished through a computer program and related hardware. The foregoing computer program may be stored in a computer-readable storage medium. When the program is executed, it performs the steps including the above method embodiments; and the foregoing storage medium includes: ROM, RAM, magnetic disks, optical disks, and various other media capable of storing program codes.

The electronic terminal provided in this embodiment comprises a processor, a memory, a transceiver, and a communication interface. The memory and the communication interface are connected to the processor and the transceiver and complete mutual communication. The memory is used for storing a computer program, the communication interface is used for communication, and the processor and the transceiver are used for running the computer program to cause the electronic terminal to execute the steps of the above method.

In this embodiment, the memory may include a Random Access Memory (RAM), and may also include a non-volatile memory, such as at least one disk memory.

The above processor may be a general-purpose processor, including a Central Processing Unit (CPU), a Network Processor (NP), and the like; it may also be a Digital Signal Processor (DSP), an Application Specific Integrated Circuit (ASIC), a Field-Programmable Gate Array (FPGA), or other programmable logic devices, discrete gate or transistor logic devices, and discrete hardware components.

The present application may be used in numerous general-purpose or special-purpose computing system environments or configurations. For example: personal computers, server computers, handheld or portable devices, tablet devices, multi-processor systems, microprocessor-based systems, set-top boxes, programmable consumer electronics devices, network PCs, minicomputers, mainframe computers, distributed computing environments including any of the above systems or devices, and the like.

The present application may be described in a general context of computer-executable instructions executed by a computer, such as program modules. Generally, program modules include routines, programs, objects, components, data structures, and the like that perform particular tasks or implement particular abstract data types. The present application may also be practiced in distributed computing environments where tasks are performed by remote processing devices connected through a communication network. In a distributed computing environment, program modules may be located in both local and remote computer storage media including storage devices.

Finally, it should be noted that the above embodiments are only used to illustrate the technical solutions of the present application and not to limit the same. Although the present application has been described in detail with reference to the preferred embodiments, those of ordinary skill in the art should understand that modifications or equivalent substitutions may be made to the technical solutions of the present application without departing from the spirit and scope of the technical solutions of the present application, and all such modifications and equivalent substitutions should be encompassed within the scope of the claims of the present application.

What is claimed is:

1. A battery fault detection method based on quantile and exponentially weighted adaptive normalization, comprising the following steps:
S1: collecting operational data of an electric vehicle (EV), comprising cell voltage data of each cell in a battery module and time parameters, and performing data preprocessing;
S2: performing Kalman filtering processing on the cell voltage data of the cells in the battery module;
S3: performing normalization processing on the cell voltage data after the filtering processing, comprising using quantiles to determine a normal value range, applying an exponentially decaying function to normal values, and applying an exponentially increasing function to outliers;
S4: calculating a Dynamic Time Warping (DTW) distance between each pair of normalized cell voltage time series, and calculating a standard score of the distances; and
S5: setting a fixed threshold, determining whether the standard score of the cell voltage exceeds the set threshold, thereby determining whether each battery cell has a fault;
wherein the step S3 comprises the following steps:
S31: using quartiles to determine the normal value range, a lower limit of the normal value range being calculated as follows:
Q₁−1.5·IQR;
an upper limit of the normal value range being calculated as follows:
Q₃+1.5·IQR;
wherein Q₁ represents a first quartile, the first quartile is a 25th percentile of the cell voltage data; Q₃ represents a third quartile, the third quartile is a 75th percentile of the cell voltage data; IQR is a difference between the third quartile Q₃ and the first quartile Q₁ in the cell voltage data set, expressed as follows:
IQR=Q₃−Q₁;
S32: based on the determined normal value range, determining normal values and outliers of the cell voltage, wherein cell voltage data within the upper and lower limit interval of the normal value range are normal values, and cell voltage data outside the upper and lower limit interval of the normal value range are outliers;
S33: applying the exponentially decaying function to the normal values, calculated as follows:
$${Z}_{α} = \frac{{x}_{i} - median}{α \cdot IQR} ,$$
$${X}_{normal \_ norm} = {e}^{- {Z}_{α}} ;$$
wherein Xᵢ represents a voltage value of each cell i; median represents a median of cell voltages, the median of cell voltages is a cell voltage value at a middle position after all cell voltage data are sorted from smallest to largest; a represents a linear adjustment parameter for normal values, α>1; Z_{α} represents a linear scaling coefficient for normal values; and X_{normal_norm} represents a value of a cell voltage normal value after exponentially decaying;
S34: applying the exponentially increasing function to the outliers, calculated as follows:
$${Z}_{β} = \frac{{x}_{i} - median}{β \cdot IQR} ,$$
$${X}_{outlier \_ norm} = {e}^{{Z}_{β}} ;$$
wherein β represents a linear adjustment parameter for outliers, 0<β<1; Z_{β} represents a linear scaling coefficient for outliers; and X_{outlier_norm} represents a value of a cell voltage outlier after exponentially increasing; and
S35: combining the processed normal values and outliers into a new normalized data set; wherein the step S4 comprises the following steps:
S41: applying a DTW algorithm, calculating the DTW distance between normalized cell voltage time series at each time point; selecting a normalized median voltage value and comparing the normalized median voltage value with each normalized cell voltage value, thereby achieving battery fault detection;
S42: calculating the standard score of distances between each cell voltage curve and a median voltage curve, expressed as follows:
$$Z = \frac{{X}_{i \_ dtw} - \overline{X}}{σ} ;$$
wherein X_{i_dtw} represents a distance between a voltage curve of cell i and the median voltage curve; X̅ represents an arithmetic mean of distances between all cell voltage curves and the median voltage curve; σ represents a standard deviation of distances between all cell voltage curves and the median voltage curve; Z is the standard score of distances between each cell voltage curve and the median voltage curve; and
S43: based on the obtained standard score of distances between each cell voltage curve and the median voltage curve, establishing a real-time online fault detection model for a traction battery based on voltage curve similarity.

2. The battery fault detection method based on quantile and exponentially weighted adaptive normalization of claim 1, wherein the step S1 comprises the following steps:
S11: collecting normal operational data of the EV, comprising a total voltage, each cell voltage, time parameters, and a Battery Management System (BMS) alarm signal;
S12: performing data processing and data cleaning on the cell voltage, and filling missing values of the data; and
S13: establishing a traction battery operational database based on the collected operational data of the battery module and each battery cell.

3. The battery fault detection method based on quantile and exponentially weighted adaptive normalization of claim 1, wherein the step S2 comprises the following steps:
S21: determining an initial state estimation and an estimation error covariance based on the processed cell voltage data;
S22: using a mean and a variance of the first few data points as the initial state estimation, predicting a state at a current time point by using a state estimation at a previous time point, and updating the estimation error covariance;
S23: calculating a Kalman gain based on a current measurement value, correcting the predicted state to obtain a more precise estimation, and updating the estimation error covariance; and
S24: performing filtering processing on each cell voltage time series, wherein a filtering process outputs a smoothed and stable data sequence at each time point.

4. The battery fault detection method based on quantile and exponentially weighted adaptive normalization of claim 1, wherein a calculation of the normal values and the outliers is based on a calculation at a current time point.

5. The battery fault detection method based on quantile and exponentially weighted adaptive normalization of claim 1, wherein the DTW algorithm in the step S41 has the following process:
the DTW algorithm finding a shortest distance path between two sequences through dynamic programming, calculated as follows:
S(i,j)=d(xᵢ, yᵢ)+min(S(i−1, j), S(i, j−1), S(i−1, j−1)),
d(xᵢ, yᵢ)=\sqrt{(xᵢ−yᵢ)²};
wherein S(i,j) represents a Euclidean distance between an i-th element of a sequence X and a j-th element of a sequence Y, and d(xᵢ, yᵢ) represents a distance between an element xᵢ of the sequence X and an element yᵢ of the sequence Y;
selecting each cell voltage sequence as the sequence X, and selecting a median voltage sequence as the sequence Y; and
the DTW algorithm tracing back from S(i,j) to S(1,1), finding a shortest path between two curves, and representing a best match of the two curves on a time axis, thereby capturing similarity between the curves.

6. The battery fault detection method based on quantile and exponentially weighted adaptive normalization of claim 1, wherein in the step S42, an arithmetic mean X bar of distances between all cell voltage curves and the median voltage curve is obtained through the DTW algorithm, expressed as follows:
$$\overline{X} = \frac{1}{N} {\sum }_{i = 1}^{N} {X}_{i \_ dtw}$$
wherein N is a total number of cells;
a standard deviation σ of distances between all cell voltage curves and the median voltage curve is obtained through the DTW algorithm, expressed as follows:
$$σ = \sqrt{\frac{1}{N} {\sum }_{i = 1}^{N} {( {X}_{i \_ dtw} - \overline{X} )}^{2}} .$$

7. The battery fault detection method based on quantile and exponentially weighted adaptive normalization of claim 1, wherein the step S5 comprises the following steps:
S51: setting an appropriate model threshold based on the standard score of distances between each cell voltage curve and the median voltage curve;
S52: determining whether each battery cell has a fault by determining whether a real-time standard score of distances between a cell voltage curve and the median voltage curve exceeds the model threshold, wherein if the standard score exceeds the model threshold, a fault is indicated, and conversely, if the standard score does not exceed the model threshold, no fault is indicated; and
S53: if a fault occurs in the battery module, locating a faulty cell based on the cell voltage where the fault occurs.

8. The battery fault detection method based on quantile and exponentially weighted adaptive normalization of claim 1, further comprising the following step:
S6: after determining that a target battery cell has a fault, executing different levels of physical protection and control responses by a main processor of a BMS, so as to realize closed-loop protection from fault detection to physical safety execution.

9. The battery fault detection method based on quantile and exponentially weighted adaptive normalization of claim 8, wherein the step S6 comprises:
S61: extracting a physical number of the faulty target battery cell and a time stamp of first triggering the fault, and determining a corresponding fault level by comparing with a preset safety risk matrix; meanwhile, writing a Diagnostic Trouble Code (DTC) into a non-volatile memory (NVM), and locking voltage time series snapshot data collected and buffered by an Analog Front End (AFE) sampling module before and after the fault is triggered;
S62: broadcasting to a Vehicle Control Unit (VCU) and an instrument panel controller through an in-vehicle communication bus, wherein broadcast content comprises a control message of the fault level, so as to drive the instrument panel controller to light up a physical fault indicator and trigger an audible-visual alarm at a vehicle level, and drive the VCU to force the entire vehicle to enter a limp-home mode in which a power output is derated to a preset safety level; wherein the limp-home mode is an operation mode in which a maximum discharge power is limited to a preset ratio of a normal value by a vehicle controller;
S63: dynamically rewriting current charge-discharge control boundaries, lowering a permitted maximum charge-discharge current threshold so as to reduce an electrochemical load of the target battery cell, and issuing a highest-priority drive command to a thermal management actuator, adjusting a coolant pump flow rate or a fan speed so as to start targeted heat dissipation of a physical region of the target battery cell; and
S64: if the fault level reaches a preset safety closed-loop cutoff threshold, the main processor immediately outputting a hardware control level to cut off a coil power supply of a high-voltage contactor or a safety relay in a main high-voltage circuit, forcing the high-voltage contactor to physically disconnect, thereby realizing topological isolation between the battery module and a high-voltage load of the entire vehicle.

10. The battery fault detection method based on quantile and exponentially weighted adaptive normalization of claim 9, wherein in the step S61, the preset safety risk matrix divides fault levels according to a magnitude of a DTW distance standard score and a number of faulty battery cells as follows:
level 1 early warning is set when a DTW distance standard score of a single battery cell exceeds a preset first threshold, monitoring is enhanced, and power output is not restricted;
level 2 alarm is set when DTW distance standard scores of a single or multiple battery cells exceed a second threshold, power derating is executed, and a maximum discharge power is limited to 70% of a normal value; and
level 3 safety is set when DTW distance standard scores of multiple battery cells exceed a third threshold, or a total voltage deviation of the battery module exceeds a preset safety boundary, and high-voltage disconnection is executed;
wherein the BMS main processor records the fault level, a physical number of the faulty cell, the time stamp, and the voltage time series snapshot in the NVM, wherein the DTC comprises a fault type identifier, an occurrence time stamp, and a fault duration counter.

11. The battery fault detection method based on quantile and exponentially weighted adaptive normalization of claim 9, wherein in the step S62:
the control message follows a Controller Area Network (CAN) 2.0B protocol, and a payload of the control message comprises a fault level identifier, a faulty cell number, and a recommended current limit value;
the BMS main processor simultaneously generates the DTC, and sends the DTC to the instrument panel through a CAN bus to trigger a pre-warning visual prompt; and
the BMS main processor further uploads fault information to a cloud server through an in-vehicle telematics terminal (T-Box), and pushes a maintenance reminder to a mobile terminal.

12. The battery fault detection method based on quantile and exponentially weighted adaptive normalization of claim 9, wherein in the steps S63 and S64, the BMS main processor further performs the following operations:
sending a hardware register rewrite command to an AFE chip of a designated channel through an isolated daisy-chain communication bus, forcibly turning off an internal or external balancing MOSFET switch corresponding to the faulty cell, and cutting off a discharge resistor path;
rewriting a PWM output duty cycle of a thermal management controller, pulling up a rotation speed of an electric liquid cooling pump to full load, or adjusting an opening of an electronic thermostat valve, so as to directionally divert a cooling medium to a module where the faulty cell is located;
if the electric vehicle is in a charging state, sending a charging current limit command to an on-board charger (OBC) through a CAN bus, so as to reduce a charging current to below a safety threshold; if the electric vehicle is in a non-charging state, sending a power limit command to a motor controller through the CAN bus, so as to limit a maximum driving power of the entire vehicle to a preset ratio of a normal value; and
when the fault level reaches Level 3 Safety, a high-side driver chip or a low-side driver chip of the BMS main processor changing a GPIO pin level state, so that a coil of the high-voltage contactor loses power, an armature of the contactor springs open, and a physical air gap is formed between a positive busbar and a negative busbar of the battery module and a high-voltage load, so as to completely cut off a current of a high-voltage busbar.

13. A battery fault detection system based on quantile and exponentially weighted adaptive normalization, comprising:
a battery module, comprising a plurality of battery cells connected in series and/or in parallel;
an AFE sampling module, electrically connected to each battery cell in the battery module through sampling wires, internally integrating a multi-channel differential analog-to-digital converter (ADC), and synchronously collecting voltage signals of each battery cell at a fixed sampling period;
a BMS main control processor, communicatively connected to the AFE sampling module through an isolated daisy-chain communication bus, wherein a non-volatile memory stores a fault detection algorithm program, and the BMS main control processor is configured to execute the method of claim 1, so as to determine whether each battery cell has a fault and determine a fault level of the battery cell;
a CAN communication module, connected to the BMS main control processor, and broadcasting a fault level control message to a VCU and an instrument panel according to the fault level;
an alarm module, connected to the BMS main control processor, and lighting up a fault indicator and triggering an audible-visual alarm according to the fault level; and
an actuator, connected to the BMS main control processor, and executing protection operations according to the fault level, wherein the protection operations comprise: turning off a balancing branch, lowering a maximum current threshold, driving a thermal management actuator to execute targeted heat dissipation, and cutting off a high-voltage contactor so as to physically disconnect an electrical connection between the battery module and a high-voltage load.

14. A battery fault detection system based on quantile and exponentially weighted adaptive normalization, comprising:
a battery module, comprising a plurality of battery cells connected in series and/or in parallel;
an AFE sampling module, electrically connected to each battery cell in the battery module through sampling wires, internally integrating a multi-channel differential ADC, and synchronously collecting voltage signals of each battery cell at a fixed sampling period;
a BMS main control processor, communicatively connected to the AFE sampling module through an isolated daisy-chain communication bus, wherein a non-volatile memory stores a fault detection algorithm program, and the BMS main control processor is configured to execute the method of claim 2, so as to determine whether each battery cell has a fault and determine a fault level of the battery cell;
a CAN communication module, connected to the BMS main control processor, and broadcasting a fault level control message to a VCU and an instrument panel according to the fault level;
an alarm module, connected to the BMS main control processor, and lighting up a fault indicator and triggering an audible-visual alarm according to the fault level; and
an actuator, connected to the BMS main control processor, and executing protection operations according to the fault level, wherein the protection operations comprise: turning off a balancing branch, lowering a maximum current threshold, driving a thermal management actuator to execute targeted heat dissipation, and cutting off a high-voltage contactor so as to physically disconnect an electrical connection between the battery module and a high-voltage load.

15. A battery fault detection system based on quantile and exponentially weighted adaptive normalization, comprising:
a battery module, comprising a plurality of battery cells connected in series and/or in parallel;
an AFE sampling module, electrically connected to each battery cell in the battery module through sampling wires, internally integrating a multi-channel differential ADC, and synchronously collecting voltage signals of each battery cell at a fixed sampling period;
a BMS main control processor, communicatively connected to the AFE sampling module through an isolated daisy-chain communication bus, wherein a non-volatile memory stores a fault detection algorithm program, and the BMS main control processor is configured to execute the method of claim 8, so as to determine whether each battery cell has a fault and determine a fault level of the battery cell;
a CAN communication module, connected to the BMS main control processor, and broadcasting a fault level control message to a VCU and an instrument panel according to the fault level;
an alarm module, connected to the BMS main control processor, and lighting up a fault indicator and triggering an audible-visual alarm according to the fault level; and
an actuator, connected to the BMS main control processor, and executing protection operations according to the fault level, wherein the protection operations comprise: turning off a balancing branch, lowering a maximum current threshold, driving a thermal management actuator to execute targeted heat dissipation, and cutting off a high-voltage contactor so as to physically disconnect an electrical connection between the battery module and a high-voltage load.

16. The battery fault detection system of claim 13, wherein:
the AFE sampling module comprises an AFE chip, wherein the AFE chip is an automotive-grade chip having a multi-channel differential ADC function, and each sampling wire is connected to a positive terminal and a negative terminal of a corresponding battery cell; and
the AFE chip reports sampling data to the BMS main control processor through the isolated daisy-chain communication bus, the BMS main control processor receives the sampling data, and adds a global time stamp to each piece of cell voltage data so as to realize time alignment.

17. The battery fault detection system of claim 13, wherein:
the BMS main control processor is a vehicle-mounted MCU running a real-time operating system conforming to an AUTOSAR standard;
the fault detection algorithm program is stored in a FLASH memory of the BMS main control processor in an embedded form, and is periodically executed at a fixed detection period under the real-time operating system; and
the BMS main control processor is further configured to store a faulty cell number, a fault occurrence time, and a detection time difference in the non-volatile memory after determining the fault.

18. The battery fault detection system of claim 13, wherein the actuator comprises:
a balancing circuit switch array, comprising a balancing MOSFET connected in parallel with each battery cell, wherein the BMS main control processor sends a register rewrite command to an AFE chip through the isolated daisy-chain communication bus so as to control on/off of the balancing MOSFET;
a thermal management actuator, comprising a liquid cooling pump, a cooling fan, a PWM drive circuit, and an electronic thermostat, wherein the BMS main control processor controls a rotation speed of the liquid cooling pump and the cooling fan by rewriting a PWM duty cycle, and controls a flow rate of a cooling medium by adjusting an opening of the electronic thermostat; and
a high-voltage relay drive circuit, comprising a high-side driver chip or a low-side driver chip, wherein the BMS main control processor controls the high-side driver chip or the low-side driver chip by changing a GPIO level output, so that a coil of the high-voltage contactor loses power, an armature springs open, and a physical air gap is formed between a positive busbar and a negative busbar of the battery module and a high-voltage load, so as to completely cut off a current of a high-voltage busbar.

19. The battery fault detection system of claim 13, wherein the BMS main control processor is further configured to:
after determining that a battery cell has a fault, extract a physical number of a faulty target battery cell and a time stamp of first triggering the fault, and determine a corresponding fault level by comparing with a preset safety risk matrix; wherein the preset safety risk matrix divides fault levels according to a magnitude of a DTW distance standard score and a number of faulty battery cells as follows:
level 1 early warning is set when a DTW distance standard score of a single battery cell exceeds a preset first threshold, monitoring is enhanced, and power output is not restricted;
level 2 alarm is set when DTW distance standard scores of a single or multiple battery cells exceed a second threshold, power derating is executed, and a maximum discharge power is limited to 70% of a normal value; and
level 3 safety is set when DTW distance standard scores of multiple battery cells exceed a third threshold, or a total voltage deviation of the battery module exceeds a preset safety boundary, and high-voltage disconnection is executed;
wherein, the BMS main control processor writes the DTC in the non-volatile memory, and locks voltage time series snapshot data collected and buffered by the AFE sampling module before and after the fault is triggered; and the DTC comprises a fault type identifier, an occurrence time stamp, and a fault duration counter.

20. The battery fault detection system of claim 13, wherein
the CAN communication module is further configured to:
broadcast a fault level control message to the VCU and an instrument panel controller through an in-vehicle communication bus according to the fault level determined by the BMS main control processor, wherein the control message follows a CAN 2.0B protocol and comprises a fault level identifier, a faulty cell number, and a recommended current limit value; and
the BMS main control processor is further configured to:
drive the instrument panel controller to light up a physical fault indicator, and trigger an audible-visual alarm;
drive the VCU to force the entire vehicle to enter a limp-home mode, wherein the limp-home mode is an operation mode in which a maximum discharge power is limited to a preset ratio of a normal value by a vehicle controller;
if an electric vehicle is in a charging state, send a charging current limit command to an on-board charger (OBC) through the CAN bus, so as to reduce a charging current to below a safety threshold;
if the electric vehicle is in a non-charging state, send a power limit command to a motor controller through the CAN bus, so as to limit a maximum driving power of the entire vehicle to a preset ratio of a normal value; and
if the fault level reaches a preset safety closed-loop cutoff threshold, the BMS main control processor changes a GPIO pin level state through a high-side driver chip or a low-side driver chip, so that a coil of the high-voltage contactor loses power, an armature springs open, and a physical air gap is formed between a positive busbar and a negative busbar of the battery module and a high-voltage load, so as to completely cut off a current of a high-voltage busbar.
